(19) United States
(12) Patent Application Publication
(10) Pub. No.: US 2022/0392964 A1
(43) Pub. Date: Dec. 8, 2022

(54) DISPLAY PANEL AND DISPLAY DEVICE

(71) Applicant: WUHAN TIANMA MICROELECTRONICS CO., LTD., Wuhan (CN)

(72) Inventors: Huangyao Wu, Xiamen (CN); Hongbo Zhou, Xiamen (CN)

(73) Assignee: WUHAN TIANMA MICROELECTRONICS CO., LTD., Wuhan (CN)

(21) Appl. No.: 17/856,409

(22) Filed: Jul. 1, 2022

Related U.S. Application Data
(63) Continuation of application No. PCT/CN2021/106207, filed on Jul. 14, 2021.

(30) Foreign Application Priority Data
Jun. 3, 2021 (CN) 202110628931.6

(51) Int. Cl. H01L 27/32; G09G 3/3233

(52) U.S. Cl. CPC H01L 27/326; G09G 3/3233; H01L 27/3234; H01L 27/3276; G09G 2300/0842

(57) ABSTRACT

A display panel and a display device are provided. In an embodiment, the display panel includes a first display region, a second display region, a third display region, and a first fan-out region, and includes first light-emitting elements and first pixel circuits. Each first pixel circuit includes a first connection point electrically connected to at least one of the first light-emitting elements through a first connection line, and each of the first pixel circuits includes a first preset transistor having a first channel. In at least one of the first pixel circuits adjacent to the first fan-out region, the first connection point is located at a side of the first channel facing away from the first fan-out region. With such a display panel, the wiring structure in a local region of the display panel is optimized, thereby alleviating a problem of insufficient wiring space in the first fan-out region.

### CROSS-REFERENCES TO RELATED APPLICATIONS

This application is a continuation of International Application No. PCT/CN2021/106207, filed on Jul. 14, 2021, which claims priority to Chinese Patent Application No. 202110628931.6, filed on Jun. 3, 2021, the disclosures of which are hereby incorporated by reference in their entireties.

### TECHNICAL FIELD

The present disclosure relates to the field of display technologies, and, in particular, to a display panel and a display device.

### BACKGROUND

In an electronic device including a display panel, a high screen-to-body ratio with better visual experience has become a trend in the development of display technologies.

Taking mobile phones and tablet computers as examples, in a scheme of a full-screen, the display panel has a first display region, a second display region, and a third display region. The first display region is reused as a photosensitive element integration region, the second display region is a normal display region, and the third display region is configured to receive pixel circuits that drive the light-emitting elements arranged in the first display region. Photosensitive elements such as a front-facing camera and an infrared sensing element can be arranged at a back of the first display region of the display panel, and light can pass through the first display region to reach the photosensitive elements to achieve corresponding functions such as front-facing shooting and infrared sensing.

For conventional display panels, a large number of wires are arranged at a junction between the third display region and the second display region, as a result, it is difficult to carry out a wiring design.

### SUMMARY

The present disclosure provides a display panel and a display device, which enhances the wiring structure of a local region of the display panel.

A first aspect of the present disclosure provides a display panel. In an embodiment, the display panel has a first display region, a second display region, a third display region, and a first fan-out region, and includes first light-emitting elements and first pixel circuits. In an embodiment, the third display region is located at least one side of the first display region in a first direction, the second display region at least partially surrounds the first display region and the third display region, a light transmittance of the first display region is greater than a light transmittance of the second display region, the first fan-out region is located between the third display region and the second display region and between the first display region and the second display region in a second direction, and the second direction intersects with the first direction. In an embodiment, the first light-emitting elements are arranged in the first display region. In an embodiment, the first pixel circuits are arranged in the third display region, each of the first pixel circuits includes a first connection point electrically connected to at least one of the first light-emitting elements through a first connection line, and each of the first pixel circuits includes a first preset transistor having a first channel. In an embodiment, in at least one of the first pixel circuits adjacent to the first fan-out region, the first connection point of each of the at least one of the first pixel circuits is located at a side of the first channel facing away from the first fan-out region.

A second aspect of the present disclosure provides a display device. In an embodiment, the display device includes the display panel described in the first aspect.

In the display panel of the present disclosure, in at least one first pixel circuit adjacent to the first fan-out region, the first connection point is located at a side of the first channel facing away from the first fan-out region, such that the first connection line corresponding to the connection point extends at a side of the first pixel circuit facing away from the first fan-out region, thereby reducing a space of the first fan-out region occupied by the first connection line, and thus facilitating the arrangement of other signal lines in the first fan-out region and alleviating a problem of insufficient wiring space in the first fan-out region.

### BRIEF DESCRIPTION OF DRAWINGS

Other features, objects and advantages of the present disclosure will become more apparent by reading the following detailed description of non-limiting embodiments with reference to the accompanying drawings, wherein the same or similar reference numerals denote the same or similar features, and the drawings are not drawn in actual scale.

FIG. 1 is a top view of a display panel according to an embodiment of the present disclosure;

FIG. 2 is a partial enlarged view of a Region Q1 shown in FIG. 1 according to an embodiment of the present disclosure;

FIG. 3 is a schematic diagram showing an equivalent circuit of a first pixel circuit in a display panel according to an embodiment of the present disclosure;

FIG. 4 is a structural schematic diagram showing a first pixel circuit in a display panel according to an embodiment of the present disclosure;

FIG. 5 is a structural schematic diagram showing a semiconductor layer of a first pixel circuit in a display panel according to an embodiment of the present disclosure;

FIG. 6 is a structural schematic diagram showing a first metal layer of a first pixel circuit in a display panel according to an embodiment of the present disclosure;

FIG. 7 is a structural schematic diagram showing a capacitive metal layer of a first pixel circuit in a display panel according to an embodiment of the present disclosure;

FIG. 8 is a structural schematic diagram showing a second metal layer and a first connection point of a first pixel circuit in a display panel according to an embodiment of the present disclosure;

FIG. 9 is a schematic diagram showing a layer structure of a display panel according to an embodiment of the present disclosure;

FIG. 10 is a schematic diagram showing a layer structure of a display panel according to another embodiment of the present disclosure;

FIG. 11 is a schematic diagram showing a layer structure of a display panel according to another embodiment of the present disclosure;

FIG. 12 is a top view of a display panel according to another embodiment of the present disclosure;

FIG. 13 is a partial enlarged view of a Region Q2 shown in FIG. 12 according to an embodiment of the present disclosure;

FIG. 14 is a partial enlarged view of the Region Q2 shown in FIG. 12 according to an embodiment of the present disclosure;

FIG. 15 is a schematic diagram showing an equivalent circuit of a second pixel circuit in a display panel according to another embodiment of the present disclosure;

FIG. 16 is a schematic diagram showing a circuit structure of a second pixel circuit in a display panel according to another embodiment of the present disclosure;

FIG. 17 is a structural schematic diagram showing a semiconductor layer of a second pixel circuit in a display panel according to an embodiment of the present disclosure;

FIG. 18 is a schematic diagram showing an equivalent circuit of a third pixel circuit in a display panel according to another embodiment of the present disclosure;

FIG. 19 is a schematic diagram showing a circuit structure of a third pixel circuit in a display panel according to another embodiment of the present disclosure;

FIG. 20 is a structural schematic diagram showing a semiconductor layer of a third pixel circuit in a display panel according to an embodiment of the present disclosure;

FIG. 21 is a top view of a display panel according to another embodiment of the present disclosure;

FIG. 22 is a partial enlarged view of a Region Q3 shown in FIG. 21 according to an embodiment of the present disclosure;

FIG. 23 is another partial enlarged view of the Region Q3 shown in FIG. 21 according to an embodiment of the present disclosure;

FIG. 24 is another partial enlarged view of the Region Q3 shown in FIG. 21 according to an embodiment of the present disclosure;

FIG. 25 is a schematic diagram showing a circuit structure of a first pixel circuit in a display panel according to another embodiment of the present disclosure;

FIG. 26 is a top view of a display panel according to another embodiment of the present disclosure;

FIG. 27 is a partial enlarged schematic view of a Q4 region shown in FIG. 26 according to an embodiment of the present disclosure;

FIG. 28 is a partial enlarged schematic view of a Q5 region shown in FIG. 27 according to an embodiment of the present disclosure;

FIG. 29 is a structural schematic diagram showing a semiconductor layer of a first pixel circuit and a second pixel circuit in a display panel according to another embodiment of the present disclosure;

FIG. 30 is a structural schematic diagram showing a first metal layer of a first pixel circuit and a second pixel circuit in a display panel according to another embodiment of the present disclosure;

FIG. 31 is a structural schematic diagram showing a capacitive metal layer of a first pixel circuit and a second pixel circuit in a display panel according to another embodiment of the present disclosure; and

FIG. 32 is a structural schematic diagram showing a second metal layer of a first pixel circuit and a second pixel circuit in a display panel according to another embodiment of the present disclosure.

### DESCRIPTION OF EMBODIMENTS

The features and exemplary embodiments of various aspects of the present disclosure will be described below. In order to make the objectives, technical solutions and advantages of the present disclosure clear, the present disclosure will be described below with reference to accompanying drawings and specific embodiments. It should be understood that the specific embodiments described herein are merely used to explain the present disclosure, and are not used to limit the present disclosure. It will be apparent to those skilled in the art that the present disclosure may be practiced without some of these details. The following description of embodiments is merely intended to provide a better illustration of the present disclosure by illustrating examples of the present disclosure.

It should be noted that, in this context, relational terms such as “first” and “second” are merely used to distinguish one entity or operation from another entity or operation, and do not necessarily require or imply any actual relationship or sequence between these entities or operations.

It will be understood that, in describing the structures of components, when a layer or region is referred to as being “on” or “over” another layer or region, it can be directly on the other layer or region, or other layers or regions can also be provided between it and the other layer or region. If the components are turned over, this layer or region will be “below” or “beneath/under” the other layer or region.

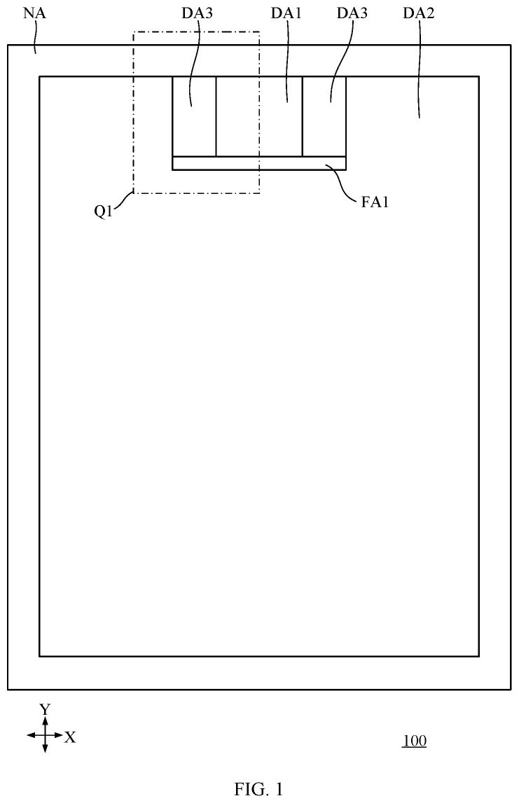

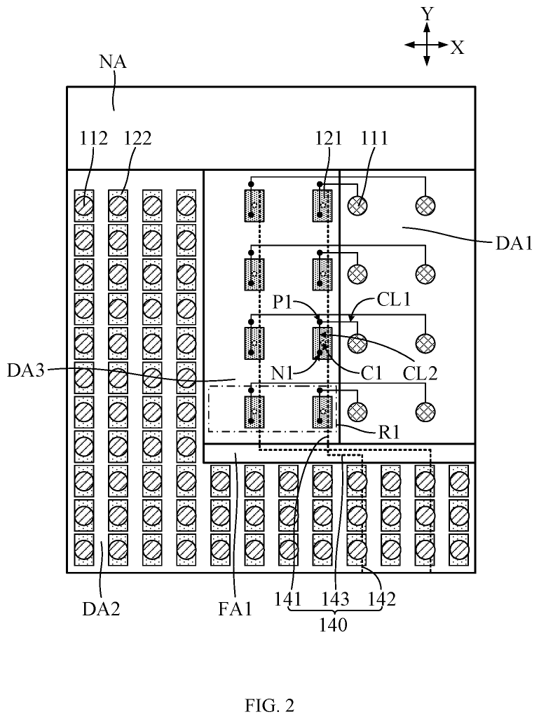

An aspect of the present disclosure provides a display panel. FIG. 1 is a top view of a display panel according to an embodiment of the present disclosure, and FIG. 2 is a partial enlarged schematic view of the Region Q1 in FIG. 1 according to an embodiment of the present disclosure.

The display panel 100 has a first display region DA1, a second display region DA2, a third display region DA3, and a first fan-out region FA1. The third display region DA3 is located on at least one side of the first display region DA1 in a first direction X. The second display region DA2 at least partially surrounds the first display region DA1 and the third display region DA3. A light transmittance of the first display region DA1 is greater than a light transmittance of the second display region DA2. The first fan-out region FA1 is located between the third display region DA3 and the second display region DA2, and between the first display region DA1 and the second display region DA2 in a second direction Y. The second direction Y intersects with the first direction X. In some embodiments, the display panel 100 further has a non-display region NA. The non-display region NA at least partially surrounds the first display region DA1, the second display region DA2 and the third display region DA3.

The display panel 100 further includes first light-emitting elements 111 and first pixel circuits 121. The first light-emitting elements 111 are arranged in the first display region DA1. The first pixel circuits 121 are located in the third display region DA3. The first pixel circuit 121 includes a first connection point P1. The first connection point P1 is electrically connected to at least one first light-emitting element 111 through a first connection line CL1. Each first pixel circuit 121 includes a first preset transistor. The first preset transistor includes a first channel C1. In an embodiment, in at least one first pixel circuit 121 adjacent to the first fan-out region FA1, the first connection point P1 is located at a side of the first channel C1 facing away from the first fan-out region FA1.

In the display panel 100 of the present disclosure, in at least one first pixel circuit 121 adjacent to the first fan-out region FA1, the first connection point P1 is located at a side of the first channel C1 facing away from the first fan-out region FA1, such that the first connection line CL1 corresponding to the connection point extends at a side of the first pixel circuit 121 facing away from the first fan-out region FA1, thereby reducing a space of the first fan-out region FA1 occupied by the first connection line CL1, and thus facilitating the arrangement of other signal lines in the first fan-out region FA1 and alleviating a problem of insufficient wiring space in the first fan-out region FA1.

In an embodiment, the first connection line CL1 may be a light-transmitting conductive connection line made of indium tin oxide (Indium Tin Oxide, ITO), or indium zinc oxide (Indium Zinc Oxide, IZO), and the like. In order to balance the light transmittance of the first display region DA1 with a resistance of the first connection line CL1, a portion of the first connection line CL1 located in the first display region DA1 can be made of a light-transmitting conductive material, and a portion of the first connection line CL1 located in the third display region DA3 can be made of a metal material with lower resistivity, which will not be elaborated herein. In addition, in order to alleviate the diffraction phenomenon of the first display region DA1, a portion of the first connection line CL1 located in the first display region DA1 may adopt a curved trace, and the first light-emitting element 111 located in the first display region DA1 may be designed to be circular or a circle-like shape. Herein, the first connection point P1 is a connection point that can be directly connected to the first connection line CL1, and the driving circuit is transmitted to the first light-emitting element 111 through the first connection point P1 and the first connection line CL1.

The embodiments of the present disclosure are described by taking the display panel 100 as an organic light-emitting diode (OLED) display panel as an example, that is, in this example, the first light-emitting element 111 is an OLED light-emitting element. It can be understood that the display panel 100 in the present disclosure may also be other self-light-emitting display panel similar to an OLED display panel that can be driven in an active matrix (AM) manner.

In this embodiment, the term “pixel circuit” refers to a smallest repeating unit of a circuit structure for driving a corresponding light-emitting element to emit light. The pixel circuit may be a 2T1C circuit, a 7T1C circuit, a 7T2C circuit, and the like. Herein, the “2T1C circuit” refers to a pixel circuit that includes two thin film transistors (T) and one capacitor (C). The “7T1C circuit” and “7T2C circuit” have similar meanings. The pixel circuit includes a driving transistor. In this embodiment, the first preset transistor is a driving transistor of the first pixel circuit 121.

In an embodiment, the display panel 100 further includes second light-emitting elements 112 and second pixel circuits 122. The second pixel circuits 122 are located in the second display region DA2. Each second pixel circuit 122 is electrically connected to at least one second light-emitting element 112 correspondingly.

The display panel 100 may further include first signal lines 140 that are connected to the first pixel circuits 121 and the second pixel circuits 122. At least one first signal line 140 includes a first signal sub-line 141, a second signal sub-line 142 and a third signal sub-line 143. The first signal sub-line 141 extends along the second direction Y in the third display region DA3, and is electrically connected to the first pixel circuits 121. The second signal sub-line 142 extends along the second direction Y in the second display region DA2, and is electrically connected to the second pixel circuits 122. The third signal sub-line 143 extends in the first fan-out region FA1 and is electrically connected to the first signal sub-line 141 and the second signal sub-line 142.

In this embodiment, in at least one first pixel circuit 121 adjacent to the first fan-out region FA1, the first connection point P1 is located at a side of the first channel C1 facing away from the first fan-out region FA1, such that a space of the first fan-out region FA1 occupied by the first connection line CL1 is reduced, thereby facilitating arranging the third signal sub-line 143 of the first signal line 140 in the first fan-out region FA1.

The first signal line 140 includes at least one of a data line, a reference voltage signal line, or a power supply line. The third signal sub-line 143 of the first signal line 140 extends in the first fan-out region FA1 and is electrically connected to the first signal sub-line 141 and the second signal sub-line 142, such that a row of first pixel circuits 121 in the third display region DA3 and a column of second pixel circuits 122 in the second display region DA2 share one first signal line 140. For example, the first signal line 140 is a data line configured to transmit a data signal for controlling a gray scale of the light-emitting element, to achieve supplying of a data signal of the first pixel circuit 121. The first fan-out region FA1 has more free wiring space, thereby facilitating the arrangement of the third signal sub-line 143 in the first fan-out region FA1.

In some embodiments, the first pixel circuits 121 are arranged in multiple rows along the second direction Y. In each row R1 of the first pixel circuits, the first pixel circuits 121 are arranged along the first direction X. In an embodiment, in at least one row R1 of the first pixel circuits adjacent to the first fan-out region FA1, the first connection point P1 of each first pixel circuit 121 is located at a side of the first channel C1 facing away from the first fan-out region FA1. In an example, one or two rows R1 of the first pixel circuits adjacent to the first fan-out region FA1 may be configured as described above in terms of the first connection point P1. In another example, all rows R1 of the first pixel circuits can be configured as described above in terms of the first connection point P1. That is, in this embodiment, the first connection point P1 of each first pixel circuit 121 is located at a side of the first channel C1 facing away from the first fan-out region FA1. When at least one row R1 of the first pixel circuits adjacent to the first fan-out region FA1 is configured as described above, the first connection line CL1 corresponding to the at least one row R1 of the first pixel circuits adjacent to the row R1 of the first pixel circuit is located at a side of the row R1 of the first pixel circuits facing away from the first fan-out region FA1, thereby reducing a space of the first fan-out region FA1 occupied by the first connection line CL1 to a greater extent, and thus alleviating a problem of insufficient wiring space in the first fan-out region FA1.

It should be noted that, in the above embodiments, in each row R1 of the first pixel circuits, the first pixel circuits 121 are arranged along the first direction X. In an actual display panel, other circuit structure may be included in the same row as at least one row R1 of the first pixel circuits. For example, the display panel 100 further includes a third pixel circuit in the same row as at least one row R1 of the first pixel circuits. The third pixel circuit is configured to drive a third light-emitting element located in the third display region DA3 to emit light. In another example, the display panel 100 further includes a dummy pixel circuit parallel to at least one row R1 of the first pixel circuits. The dummy pixel circuit may be a pixel circuit whose circuit structure is the same as or similar to that of the first pixel circuit 121 and cannot make the light-emitting element emit light, for example, the pixel circuit lacks a certain layer or structure, or the pixel circuit is not electrically connected to the light-emitting element. In some embodiments, the display panel may include a dummy light-emitting element in the same row as at least one row R1 of the first pixel circuits, for example, an anode, a pixel definition layer opening, a light-emitting material, and a cathode are provided, but no corresponding pixel circuit is provided; or, one or more of an anode, a pixel definition layer opening, a light-emitting material, and a cathode are not provided. When the display panel 100 includes a third pixel circuit and/or a dummy pixel circuit and/or a dummy light-emitting element in the same row as at least one row R1 of the first pixel circuits, the third pixel circuit and/or the dummy pixel circuit may be interposed among the first pixel circuits 121, or may also be located at a side of multiple first pixel circuits 121.

In an embodiment, the first pixel circuit 121 includes a first node N1 configured to transmit a driving current to the first light-emitting element 111. The first node N1 is located at a side of the first channel C1.

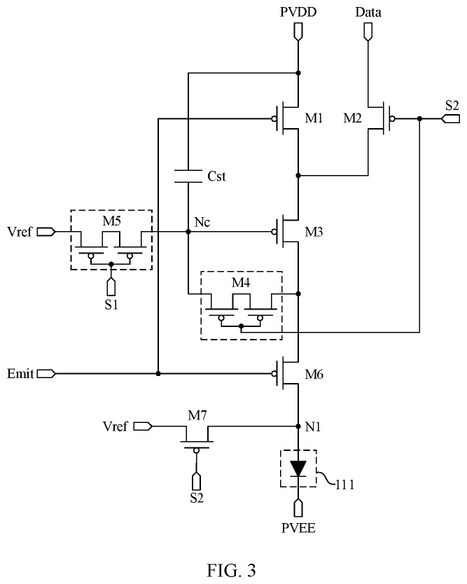

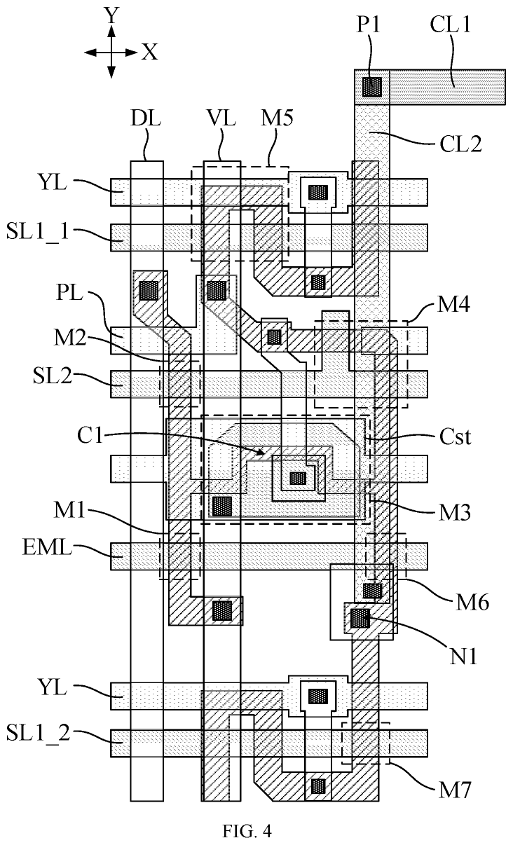

FIG. 3 is a schematic diagram showing an equivalent circuit of a first pixel circuit in a display panel according to an embodiment of the present disclosure; and FIG. 4 is a structural schematic diagram showing a first pixel circuit in a display panel according to an embodiment of the present disclosure.

In an embodiment, for example, the first pixel circuit 121 is a 7T1C circuit, that is, the first pixel circuit 121 includes seven transistors M1 to M7 and a storage capacitor Cst. A reference voltage signal line YL is used to provide a reference voltage signal Vref for resetting a preset node Nc of the first pixel circuit 121. For a current row of the first pixel circuits 121, a first scan line SL1_1 is configured to provide a first scan signal S1, a second scan line SL2 is configured to provide a second scan signal S2. The first scan lines SL1_2 in a next row can be connected to the first scan lines SL1_2 in the current row, such that the current row can be provided with the second scan signal S2, and the next row of the first pixel circuits 121 can be provided with the first scan signal S1. A light-emitting control line EML is configured to provide a light-emitting control signal Emit. In some embodiments, the display panel 100 may further include a data line DL configured to provide a data signal Data, and a power line VL configured to provide a power supply signal PVDD. In an embodiment, the transistor M4 is a double-gate transistor, and thus includes two sub-transistors. A part of the semiconductor layer connected between the two sub-transistors may be doped with impurities to have conductivity. In an embodiment, the first pixel circuit 121 further includes a shielding line (or a shielding structure) PL. The shielding line PL may be in the same layer as the reference voltage line signal line YL and may be electrically connected to the power supply line VL so as to have a constant voltage. An orthographic projection of the shielding line PL on the semiconductor layer shields at least part of the semiconductor layer between the two sub-transistors of the transistor M4. Since the shielding line PL has a constant voltage, signal interference to the transistor M4 by other signal lines can be reduced.

The first pixel circuit 121 may be configured to include at least one semiconductor layer and multiple conductive layers, e.g., the conductive layer is a metal layer. In an embodiment, the first pixel circuit 121 at least includes a semiconductor layer, a first metal layer, a capacitor metal layer and a second metal layer. In some embodiments, the first pixel circuit 121 may further include other conductive layers, such as a third metal layer and the like.

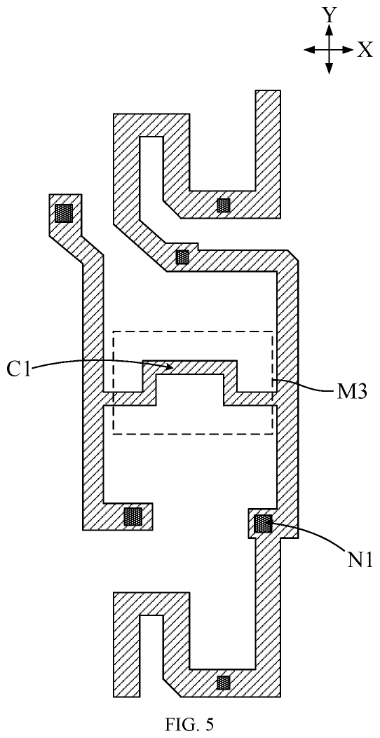

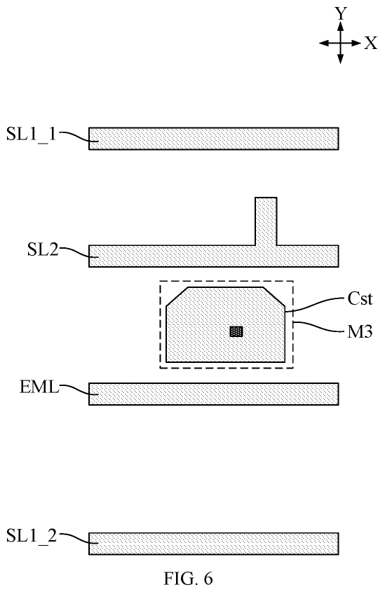

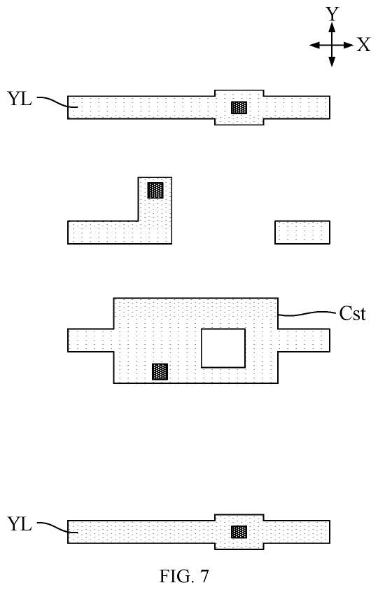

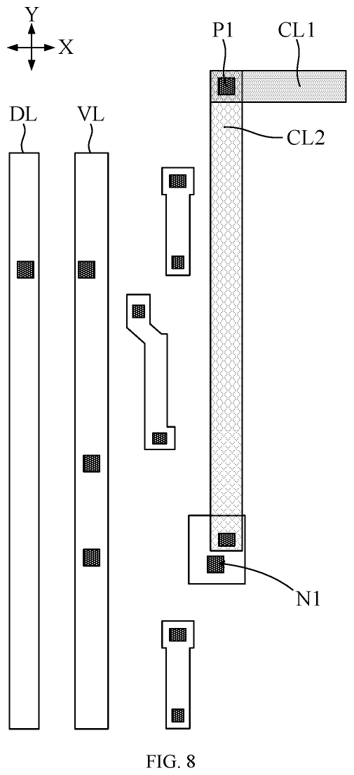

FIG. 5 is a structural schematic diagram showing a semiconductor layer of a first pixel circuit in a display panel according to an embodiment of the present disclosure; FIG. 6 is a structural schematic diagram showing a first metal layer of a first pixel circuit in a display panel according to an embodiment of the present disclosure; FIG. 7 is a structural schematic diagram showing a capacitive metal layer of a first pixel circuit in a display panel according to an embodiment of the present disclosure; and FIG. 8 is a structural schematic diagram showing a second metal layer and a first connection point of a first pixel circuit in a display panel according to an embodiment of the present disclosure. In addition to the second metal layer, some structural layers related to the first connection point are also shown in FIG. 8.

As shown in FIG. 3 to FIG. 8, the transistors M1 to M7 of the first pixel circuit 121 include a driving transistor M3, a first light-emitting control transistor M1 and a second light-emitting control transistor M6. The driving transistor M3 can transmit a driving current to the first light-emitting element 111. The gate electrode of the driving transistor M3 is connected to the aforementioned preset node Nc, and the preset node Nc is connected to an electrode plate of the storage capacitor Cst. Each of the gate electrode of the first light-emitting control transistor M1 and the gate electrode of the second light-emitting control transistor M6 is connected to the light-emitting control line EML. The first light-emitting control transistor M1 is connected between the power supply line VL and the driving transistor M3. The second light-emitting control transistor M6 is connected between the driving transistor M3 and the anode of the first light-emitting element 111. The first node N1 is located between the second light-emitting control transistor M6 and the anode of the first light-emitting element 111.

In an embodiment, in the storage capacitor Cst, the electrode plate electrically connected to the power supply line VL is electrically connected to the electrode plate of the adjacent first pixel circuit 121 in the same layer, to reduce a voltage drop of the power supply line VL.

As shown in FIG. 4 and FIG. 5, in an embodiment, the first preset transistor is a driving transistor M3 of the first pixel circuit 121, and a first channel C1 is the channel of the driving transistor M3 of the first pixel circuit 121. As shown in FIG. 4, in an embodiment, the first node N1 is at a position of a first through-hole when the second light-emitting control transistor M6 is connected to the anode of the first light-emitting element 111. As shown in FIG. 4, FIG. 5, and FIG. 8, in an embodiment, the first node N1 is at a position of a through-hole that connects the second metal layer to the semiconductor layer when the second light-emitting control transistor M6 is connected to the anode of the first light-emitting element 111. The through-hole where the first node N1 is located can be electrically connected to the anode of the first light-emitting element 111 through other conductive structures such as a conductive structure located in the third metal layer.

As shown in FIG. 2 and FIG. 4, in an embodiment, in at least one first pixel circuit 121, the first node N1 is located at a side of the first channel C1 facing the first fan-out region FA1, and the first connection point P1 is electrically connected to the first node N1 through the second connection line CL2. According to the display panel 100 of the present embodiment, when the first node N1 is located at a side of the first channel C1 facing the first fan-out region FA1, the first node N1 is electrically connected to the first connection point P1 at a side facing away from the first fan-out region FA1 through the second connection line CL2, such that a position occupied by the first connection line CL1 can be changed without significantly changing a structure of the original first pixel circuit 121 and a sequence of the signal lines. The first connection lines CL1 originally required to be arranged at a side facing the first fan-out region FA1 is changed to be arranged at a side facing away from the first fan-out region FA1. Therefore, the display panel 100 realizes a space avoidance of the first connection line CL1 in the first fan-out region FA1 with a small change in the circuit structure, thereby facilitating the arrangement of the first signal line 140 in the first fan-out region FA1.

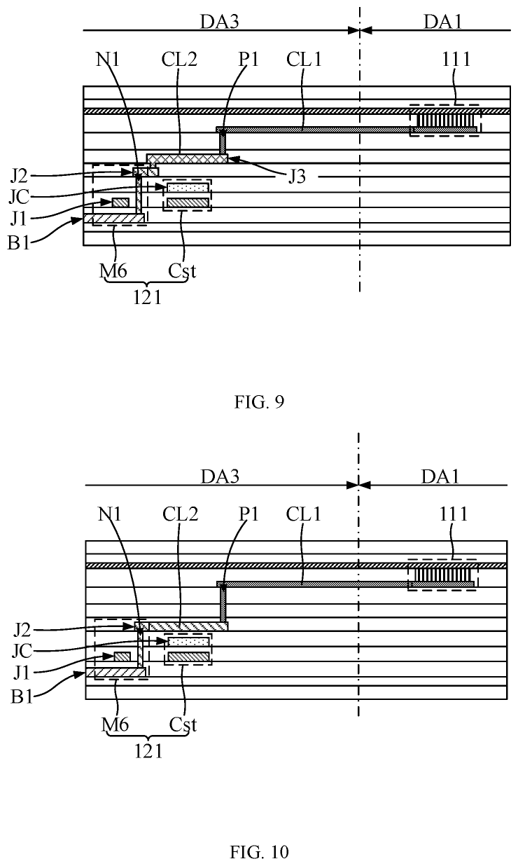

FIG. 9 is a schematic diagram showing a layer structure of a display panel according to an embodiment of the present disclosure. As shown in FIG. 4 to FIG. 9, in an embodiment, the first pixel circuit 121 includes a semiconductor layer B1, a first metal layer J1, a capacitor metal layer JC, a second metal layer J2 and a third metal layer J3. The first node N1 is at a position of the first through-hole when the second light-emitting control transistor M6 is connected to the anode of the first light-emitting element 111. In an embodiment, the first node N1 is at a position of the through-hole that connects the second metal layer J2 to the semiconductor layer B1 when the second light-emitting control transistor M6 is connected to the anode of the first light-emitting element 111. In an embodiment, at least part of the second connection line CL2 is located in the third metal layer J3, and at least part of the first connection line CL1 is arranged in the same layer as the anode of the first light-emitting element 111. In this case, the first connection point P1 is at a position of the through-hole that connects the first connection line CL1 to the second connection line CL2, i.e., a position of the through-hole that connects the layer where the anode is located to the third metal layer J3.

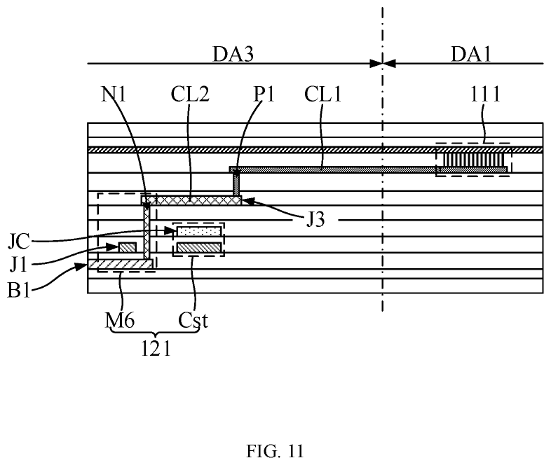

FIG. 10 is a schematic diagram showing a layer structure of a display panel according to another embodiment of the present disclosure; and FIG. 11 is a schematic diagram showing a layer structure of a display panel according to another embodiment of the present disclosure.

As shown in FIG. 10, the first pixel circuit 121 includes a semiconductor layer B1, a first metal layer J1, a capacitor metal layer JC, and a second metal layer J2. The first node N1 is at a position of a first through-hole when the second light-emitting control transistor M6 is connected to the anode of the first light-emitting element 111. In the embodiment shown in FIG. 10, the first node N1 is at a position of a through-hole that connects the second metal layer J2 to the semiconductor layer B1 when the second light-emitting control transistor M6 is connected to the anode of the first light-emitting element 111. In the embodiment involved in FIG. 10, at least part of the second connection line CL2 is located in the second metal layer J2, and at least part of the first connection line CL1 is in the same layer as the anode of the first light-emitting element 111, in this case, the first connection point P1 is at a position of the through-hole that connects the first connection line CL1 to the second connection line CL2, that is, a position of a through-hole that connects the layer where the anode is located to the second metal layer J2.

As shown in FIG. 11, the first pixel circuit 121 includes a semiconductor layer B1, a first metal layer J1, a capacitor metal layer JC, a second metal layer and a third metal layer J3. The first node N1 is at a position of a first through-hole when the second light-emitting control transistor M6 is connected to the anode of the first light-emitting element 111. In the embodiment shown in FIG. 11, the first node N1 is at a position of a through-hole that connects the third metal layer J3 to the semiconductor layer B1 when the second light-emitting control transistor M6 is connected to the anode of the first light-emitting element 111. In the embodiment involved in FIG. 11, at least part of the second connection line CL2 is located in the third metal layer J3, and at least part of the first connection line CL1 is arranged in the same layer as the anode of the first light-emitting element 111. In this case, the first connection point P1 is at a position of a through-hole that connects the first connection line CL1 to the second connection line CL2, that is, a position of a through-hole that connects the layer where the anode is located to the third metal layer J3.

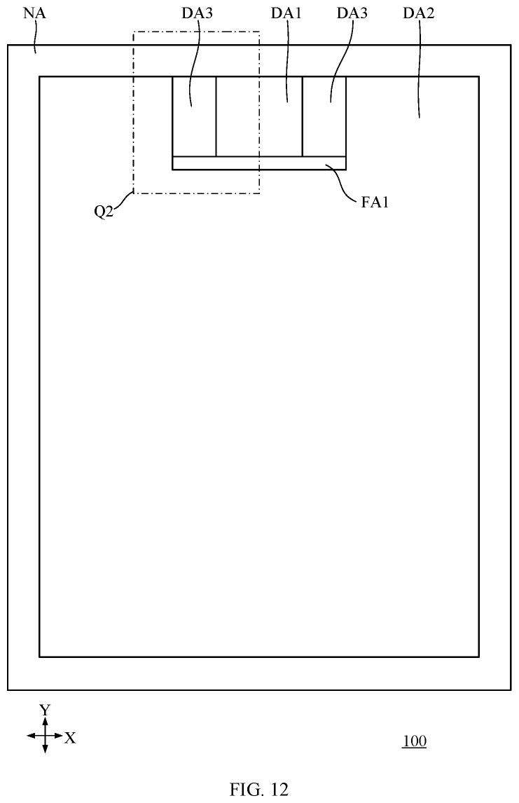

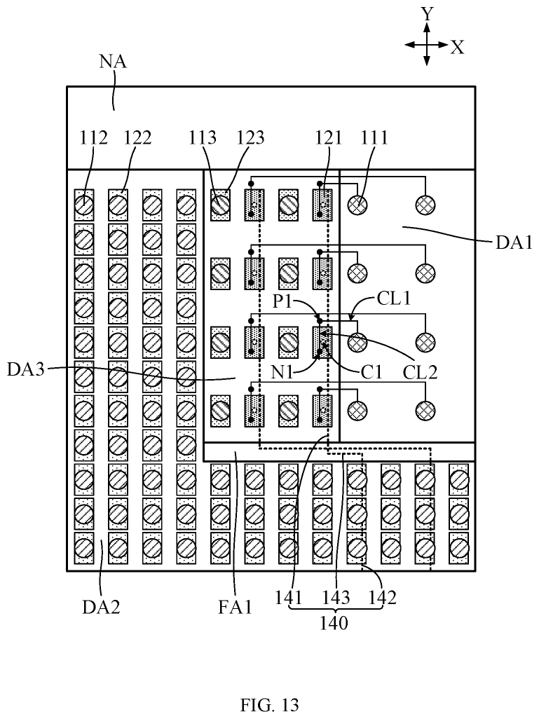

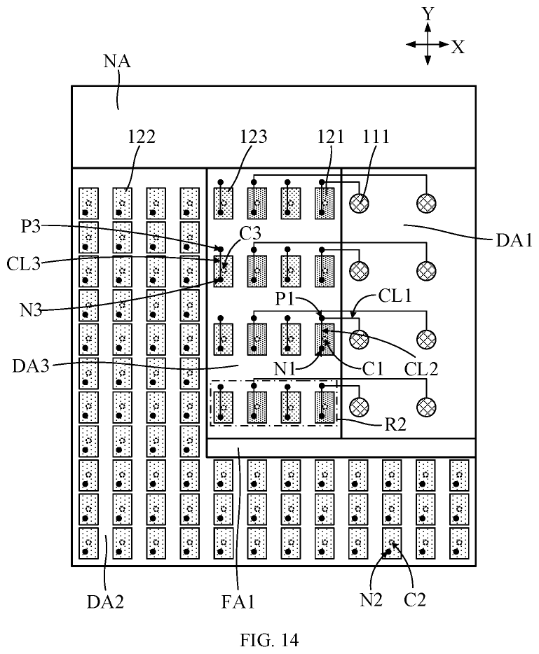

FIG. 12 is a top view of a display panel according to another embodiment of the present disclosure, and FIG. 13 and FIG. 14 are partially enlarged views of a region Q2 shown in FIG. 12. In an embodiment, the display panel 100 further includes second light-emitting elements 112, third light-emitting elements 113, second pixel circuits 122, third pixel circuits 123 and first signal lines 140. The second light-emitting elements 112 are arranged in the second display region DA2. The third light-emitting elements 113 are arranged in the third display region DA3. The second pixel circuits 122 are arranged in the second display region DA2. Each second pixel circuit 122 is electrically connected to at least one second light-emitting element 112 correspondingly. The third pixel circuits 123 are arranged in the third display region DA3. Each third pixel circuit 123 is electrically connected to at least one third light-emitting element 113 correspondingly.

At least one first signal line 140 includes a first signal sub-line 141, a second signal sub-line 142 and a third signal sub-line 143. The first signal sub-line 141 extends along the second direction Y in the third display region DA3, and is electrically connected to the first pixel circuits 121. The second signal sub-line 142 extends along the second direction Yin the second display region DA2, and is electrically connected to the second pixel circuits 122. The third signal sub-line 143 extends in the first fan-out region FA1, and is electrically connected to the first signal sub-line 141 and the second signal sub-line 142.

As shown in FIG. 14, in some embodiments, each second pixel circuit 122 includes a second preset transistor. The second preset transistor has a second channel C2. The second pixel circuit 122 includes a second node N2 configured to transmit a driving current to the second light-emitting element 112. The second node N2 is located at a side of the second channel C2.

In an embodiment, an equivalent circuit and a circuit structure of the first pixel circuit 121 are essentially the same as the embodiments shown in FIG. 3 and FIG. 4, and the first pixel circuit 121 will not be elaborated herein.

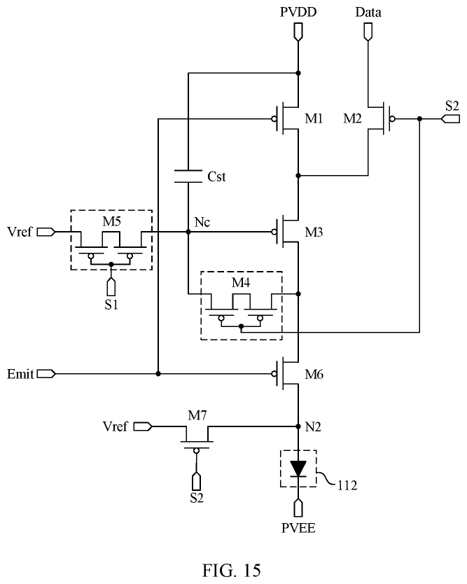

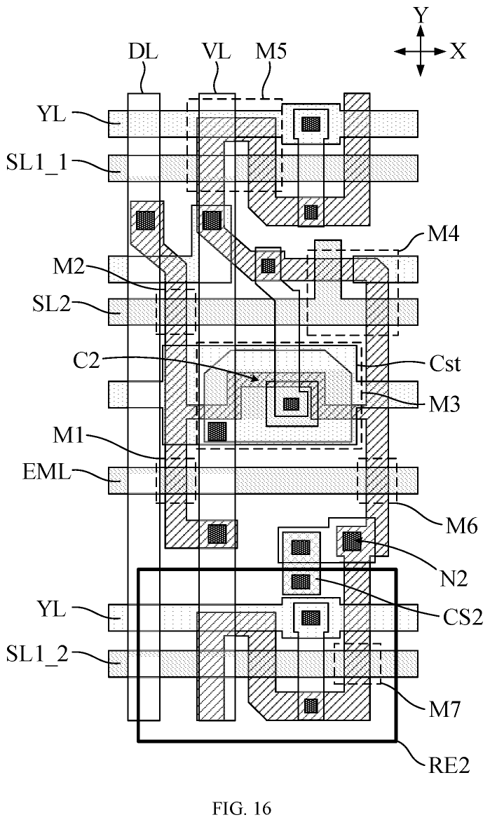

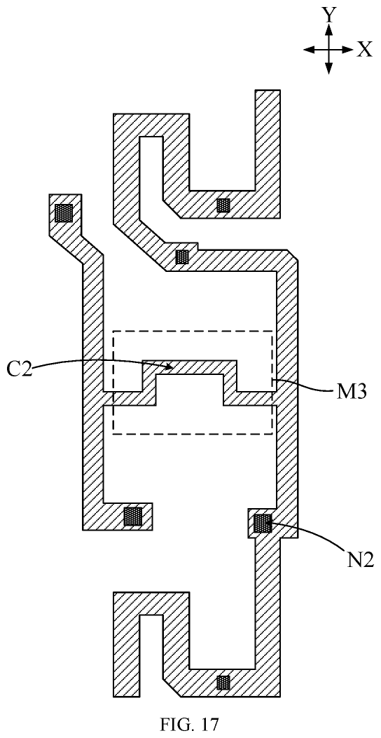

FIG. 15 is a schematic diagram showing an equivalent circuit of a second pixel circuit in a display panel according to another embodiment of the present disclosure; and FIG. 16 is a schematic diagram showing a circuit structure of a second pixel circuit in a display panel according to another embodiment of the present disclosure. The second pixel circuit 122 at least includes a semiconductor layer, a first metal layer, a capacitor metal layer, and a second metal layer. FIG. 17 is a structural schematic diagram showing a semiconductor layer of a second pixel circuit in a display panel according to an embodiment of the present disclosure.

In an embodiment, the second pixel circuit 122 is a 7T1C circuit, which includes seven transistors M1 to M7 and a storage capacitor Cst. An equivalent circuit and a circuit structure of the second pixel circuit 122 are similar to those of the first pixel circuit 121, the differences will be described below, and the similarities will not be elaborated.

Referring to FIG. 15 to FIG. 17, in an embodiment, the second preset transistor is the driving transistor M3 of the second pixel circuit 122, and the second channel C2 is the channel of the driving transistor M3 of the second pixel circuit 122. As shown in FIG. 16 and FIG. 17, in an embodiment, the second node N2 is at a position of a first through-hole when the second light-emitting control transistor M6 is connected to the anode of the second light-emitting element 112. In an embodiment, the second node N2 is at a position of a through-hole that connects the second metal layer to the semiconductor layer when the second light-emitting control transistor M6 is connected to the anode RE2 of the second light-emitting element 112. The through-hole where the second node N2 is located can be electrically connected to the anode RE2 of the second light-emitting element 112 through other conductive structures, such as the conductive structure CS2 located in the third metal layer.

In an embodiment, an orientation of the first node N1 of the first pixel circuit 121 relative to the first channel C1 is the same as an orientation of the second node N2 of the second pixel circuit 122 relative to the second channel C2. Therefore, the arrangement order of multiple signal lines that are configured to transmit signals to the first pixel circuit 121 and the second pixel circuit 122 is largely unchanged, and there is no need to significantly change the wiring of the display panel 100.

As shown in FIG. 14, in some embodiments, at least one third pixel circuit 123 includes a third connection point P3. The third light-emitting element 113 is electrically connected to the third pixel circuit 123 through the third connection point P3. The third pixel circuit 123 includes a third preset transistor that has a third channel C3. In at least one third pixel circuit 123 adjacent to the first fan-out region FA1, the third connection point P3 is located at a side of the third channel C3 facing away from the first fan-out region FA1. When the third pixel circuit 123 and the third light-emitting element 113 need to be connected by connection lines, the third connection point P3 is located at a side of the third channel C3 facing away from the first fan-out region FA1, such that a space of the first fan-out region FA1 occupied by the connection line that is connected to the third pixel circuit 123 can be reduced, thereby further improving the flexibility of other wirings in the first fan-out region FA1.

In some embodiments, multiple first pixel circuits 121 and multiple third pixel circuits 123 are arranged in multiple rows along the second direction Y. In each row R2 of the first pixel circuits and the third pixel circuits, multiple first pixel circuits 121 and multiple third pixel circuits 123 are arranged along the first direction X. In an embodiment, in at least one row R2 of the first pixel circuits and the third pixel circuits that is adjacent to the first fan-out region FA1, the first connection point P1 of each first pixel circuit 121 is located at a side of the first channel C1 facing away from the first fan-out region FA1, and the third connection point P3 of each third pixel circuit 123 is located at a side of the third channel C3 facing away from the first fan-out region FA1, thereby reducing a space of the first fan-out region FA1 occupied by the first connection line CL1 and a connection line connected to the third pixel circuit 123 to a greater extent, and thus alleviating a problem of insufficient wiring space in the first fan-out region FA1.

In an actual display panel, the display panel may include other circuit structures in the same row as at least one row R2 of first pixel circuits and the third pixel circuits, for example, the display panel 100 further includes a dummy pixel circuit located in the same row as at least one row R2 of the first pixel circuits and the third pixel circuits. The dummy pixel circuit may be a pixel circuit whose circuit structure is the same as or similar to that of the first pixel circuit 121 and is not electrically connected to the light-emitting element. The dummy pixel circuit may be interposed between the first pixel circuits 121 and/or the third pixel circuit 123, or may be located at a side of all the first pixel circuits 121 and/or the third pixel circuits 123.

In some embodiments, the third pixel circuit 123 includes a third node N3 configured to transmit a driving current to the third light-emitting element 113. The third node N3 is located at a side of the third channel C3. The third connection point P3 is electrically connected to the third node N3 through the third connection line.

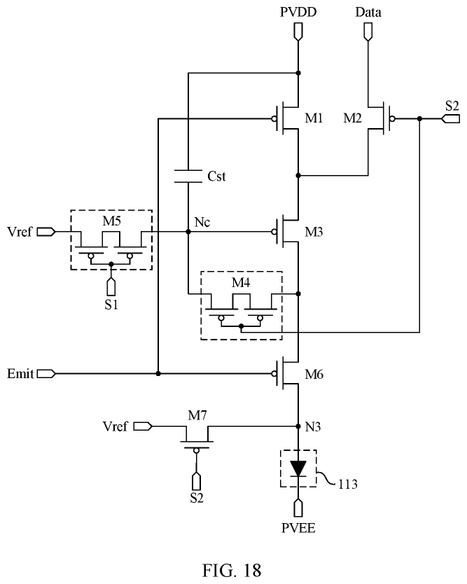

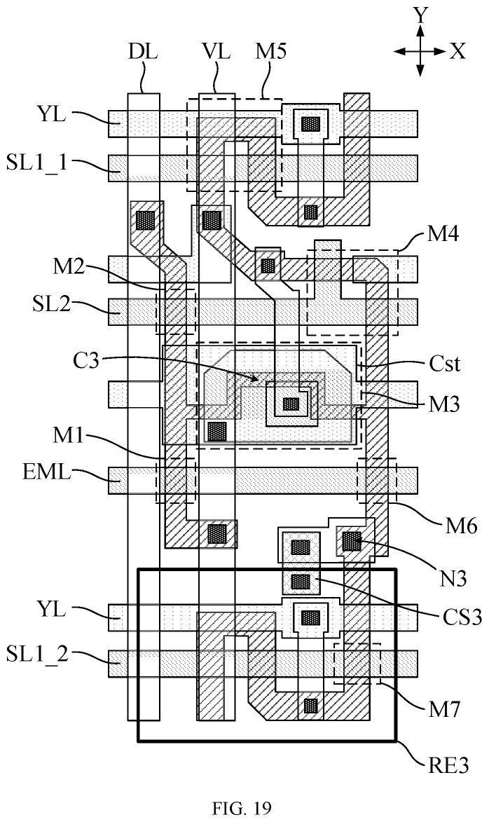

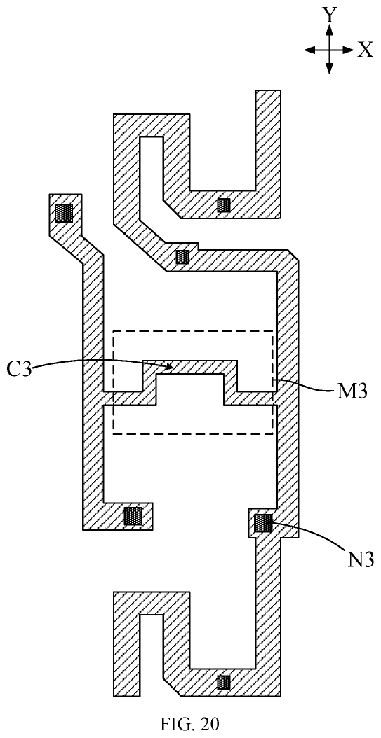

FIG. 18 is a schematic diagram showing an equivalent circuit of a third pixel circuit in a display panel according to another embodiment of the present disclosure; and FIG. 19 is a schematic diagram showing a circuit structure of a third pixel circuit in a display panel according to another embodiment of the present disclosure. The third pixel circuit 123 at least includes a semiconductor layer, a first metal layer, a capacitor metal layer, and a second metal layer. FIG. 20 is a structural schematic diagram showing a semiconductor layer of a third pixel circuit in a display panel according to an embodiment of the present disclosure.

In an embodiment, the third pixel circuit 123 is a 7T1C circuit, which includes seven transistors M1 to M7 and a storage capacitor Cst. An equivalent circuit and a circuit structure of the third pixel circuit 123 are similar to those of the first pixel circuit 121, the differences will be described below, and the similarities will not be elaborated.

Referring to FIG. 18 to FIG. 20, in an embodiment, the third preset transistor is the driving transistor M3 of the third pixel circuit 123, and the third channel C3 is the channel of the driving transistor M3 of the third pixel circuit 123. As shown in FIG. 19 and FIG. 20, in an embodiment, the third node N3 is at a position of a first through-hole when the second light-emitting control transistor M6 is connected to the anode of the third light-emitting element 113. In an embodiment, the third node N3 is at a position of a through-hole that connects the second metal layer to the semiconductor layer when the second light-emitting control transistor M6 is connected to the anode RE3 of the third light-emitting element 113. The through-hole where the third node N3 is located can be electrically connected to the anode RE3 of the third light-emitting element 113 through other conductive structures, such as the conductive structure CS3 located in the third metal layer.

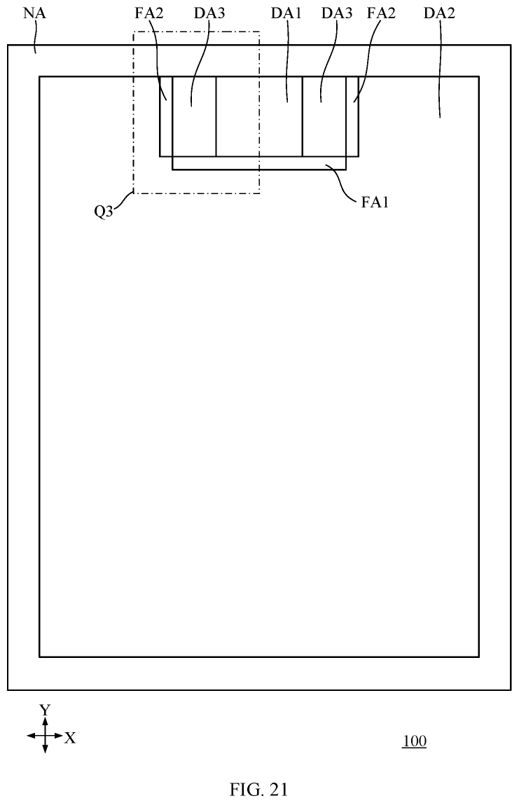

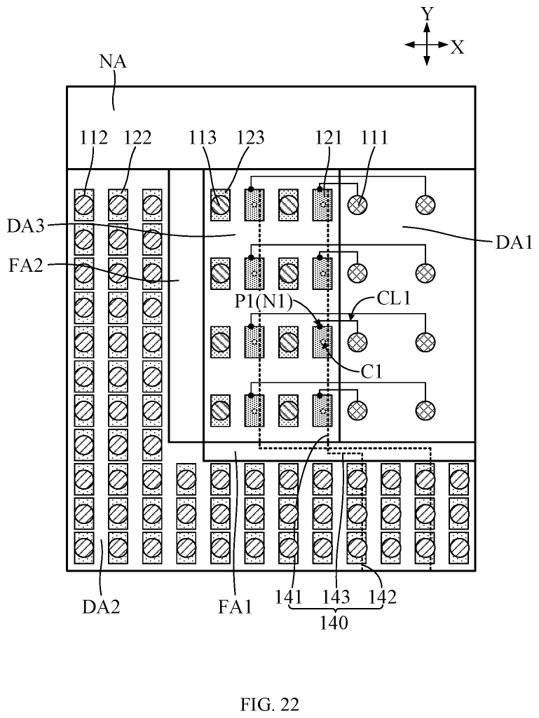

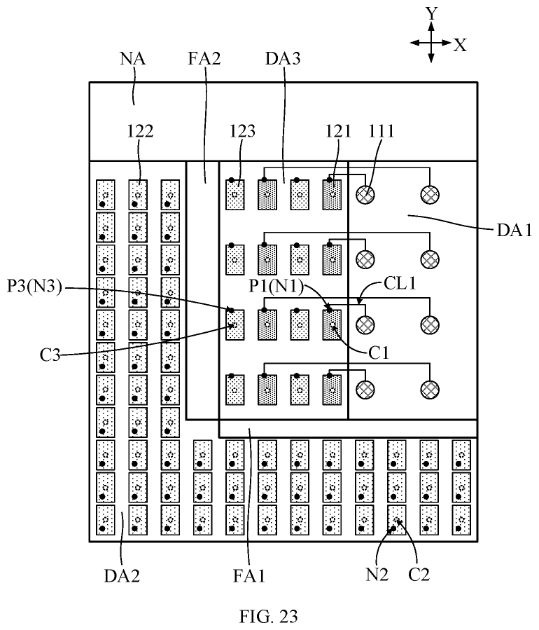

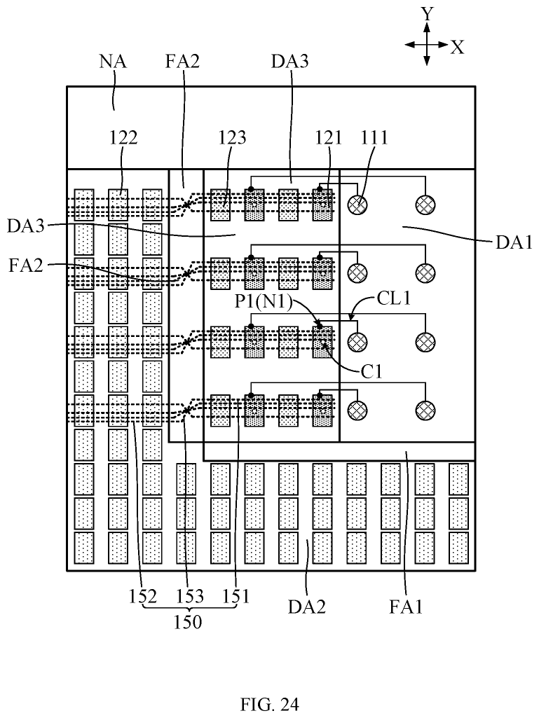

FIG. 21 is a top view of a display panel according to another embodiment of the present disclosure, and FIG. 22, FIG. 23 and FIG. 24 are partial enlarged schematic views of a region Q3 shown in FIG. 21. In an embodiment, the first pixel circuit 121 includes a first node N1 configured to transmit a driving current to the first light-emitting element 111, and the first node N1 is located at a side of the first channel C1. In at least one first pixel circuit 121, the first connection point P1 coincides with the first node N1. In this case, the first node N1 is already located at a side of the first channel C1 facing away from the first fan-out region FA1, thereby reducing a space of the first fan-out region FA1 occupied by the first connection line CL1, and thus facilitating the arrangement of the third signal sub-lines 143 of the first signal line 140 in the first fan-out region FA1. In this embodiment, it is no longer necessary to provide the second connection line CL2, such that a signal influence caused by overlapping of the second connection line CL2 with the wires in the first pixel circuit 121 can be avoided, thereby reducing a possibility of uneven display of the display panel 100.

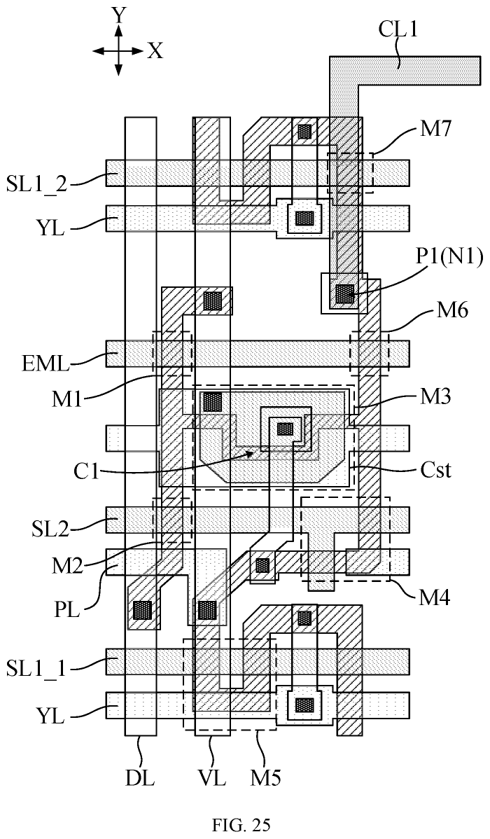

In an embodiment, an equivalent circuit of the first pixel circuit 121 is similar to the embodiment shown in FIG. 3. FIG. 25 is a schematic diagram showing a circuit structure of a first pixel circuit in a display panel according to another embodiment of the present disclosure. In an embodiment, a circuit structure of the first pixel circuit 121 is essentially equivalent to a mirror of a circuit structure of the embodiment shown in FIG. 12, wherein these two are mirror structures in a direction perpendicular to the second direction Y.

In an embodiment, an equivalent circuit and a circuit structure of the second pixel circuit 122 are similar to the embodiments shown in FIG. 15 and FIG. 16, and will not be elaborated herein.

In an embodiment, an orientation of the first node N1 of the first pixel circuit 121 relative to the first channel C1 is opposite to an orientation of the second node N2 of the second pixel circuit 122 relative to the second channel C2. In an embodiment, a circuit structure of the first pixel circuit 121 is essentially equivalent to a mirror of a circuit structure of the second pixel circuit 122, wherein these two are mirror structures in a direction perpendicular to the second direction Y.

As shown in FIG. 24, in some embodiments, the display panel 100 further includes a second fan-out region FA2. The second fan-out region FA2 is located between the third display region DA3 and the first display region DA1 in the first direction X. The display panel 100 further includes second signal lines 150. At least one second signal line 150 includes a fourth signal sub-line 151, a fifth signal sub-line 152 and a sixth signal sub-line 153. The fourth signal sub-line 151 extends along the first direction X in the third display region DA3, and is electrically connected to the first pixel circuits 121. The fifth signal sub-line 152 extends along the first direction X in the second display region DA2, and is electrically connected to the second pixel circuits 122. The sixth signal sub-line 153 extends in the second fan-out region FA2 and is electrically connected to the first signal sub-line 141 and the second signal sub-line 142.

A row of pixel circuits (including the first pixel circuit 121 and/or the third pixel circuit 123) in the third display region DA3 and a row of second pixel circuits 122 in the second display region DA2 share one second signal line 140, thereby achieving signal supply of the first pixel circuit 121 and/or the third pixel circuit 123 in the third display region DA3.

In some embodiments, each first pixel circuit 121 is electrically connected to N second signal lines 150, where N is an integer greater than or equal to 2. Among N second signal lines 150 corresponding to each first pixel circuit 121, the arrangement order of N fourth signal sub-lines 151 along the second direction Y is opposite to the arrangement order of N fifth signal sub-lines 152 along the second direction Y. The second signal lines 150 include at least one of a scan line, a reference voltage signal line, or a light-emitting control line. For example, each first pixel circuit 121 corresponds to four second signal lines 150, i.e., the first scan line SL1, the second scan line SL2, the light-emitting control line EML and the reference voltage signal line YL. By setting the second fan-out region FA2, N fourth signal sub-lines 151 and N fifth signal sub-lines 152 can achieve wire changing by the through-hole by the corresponding N sixth signal sub-lines 153 in the second fan-out region FA2, to achieve changing of the arrangement order in the second direction Y. In an example, a row of the first pixel circuits 121 and the third pixel circuits 123 and a corresponding row of the second pixel circuits 122 share four second signal lines 150, and the four second signal lines 150 have different arrangement orders in different display regions. In the third display region DA3, from top to bottom along the second direction Y, the four fourth signal sub-lines 151 are the first scan line SL1, the reference voltage signal line YL, the light-emitting control line EML, and the second scan line SL2 in sequence. In the second display region DA2, also from top to bottom along the second direction Y, the four fifth signal sub-lines 152 are the second scan line SL2, the light-emitting control line EML, the reference voltage signal line YL, and the first scan line SL1 in sequence; and the arrangement order of the four fifth signal sub-lines 152 is opposite to the arrangement order of the four fourth signal sub-lines 151.

In some embodiments, the display panel 100 includes wiring layers. Each wiring layer is provided with a patterned wire structure that may be made of a metal material or a semiconductor material. In an embodiment, among N second signal lines 150 corresponding to each first pixel circuit 121, at least two of N sixth signal sub-lines 153 are located in different wiring layers, so as to avoid signal interference among the six signal sub-lines 153 transmitting different signals, thereby achieving change of the arrangement order of the N second signal lines 150 along the second direction Y.

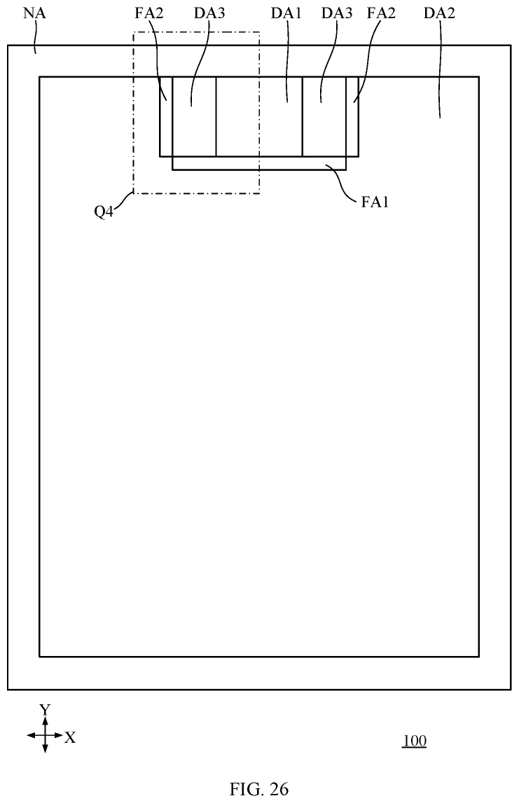

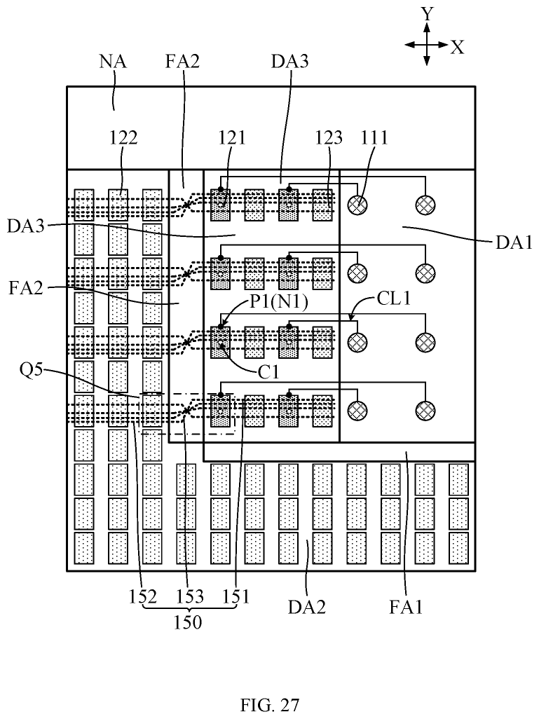

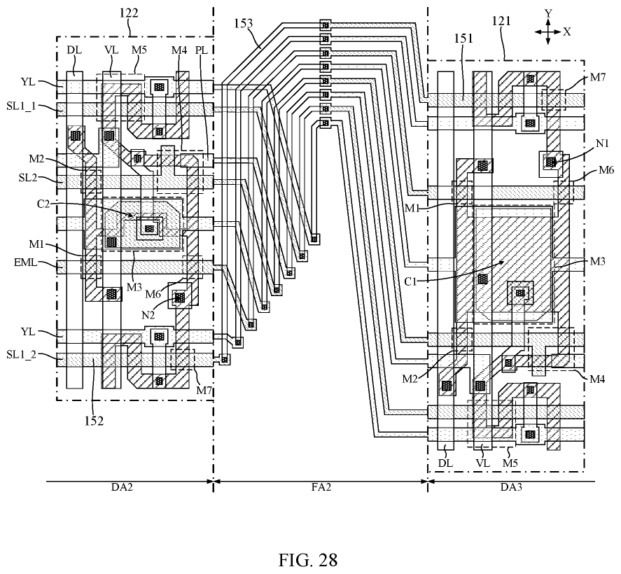

FIG. 26 is a top view of a display panel according to another embodiment of the present disclosure; FIG. 27 is a partial enlarged schematic view of a Q4 region shown in FIG. 26 according to an embodiment of the present disclosure; and FIG. 28 is a partial enlarged schematic view of a Q5 region shown in FIG. 27 according to an embodiment of the present disclosure.

In an embodiment, an equivalent circuit and a circuit structure of the second pixel circuit 122 are similar to the embodiments shown in FIG. 15 and FIG. 16, and will not be elaborated herein.

In an embodiment, an equivalent circuit of the first pixel circuit 121 is similar to the embodiment shown in FIG. 3, but a circuit structure of the first pixel circuit 121 differs from a mirror of the circuit structure shown in FIG. 12, that is, the circuit structure of the first pixel circuit 121 in this embodiment is different from that of the embodiment shown in FIG. 25.

In an embodiment, the first pixel circuit 121 and the second pixel circuit 122 at least include a semiconductor layer, a first metal layer, a capacitor metal layer and a second metal layer.

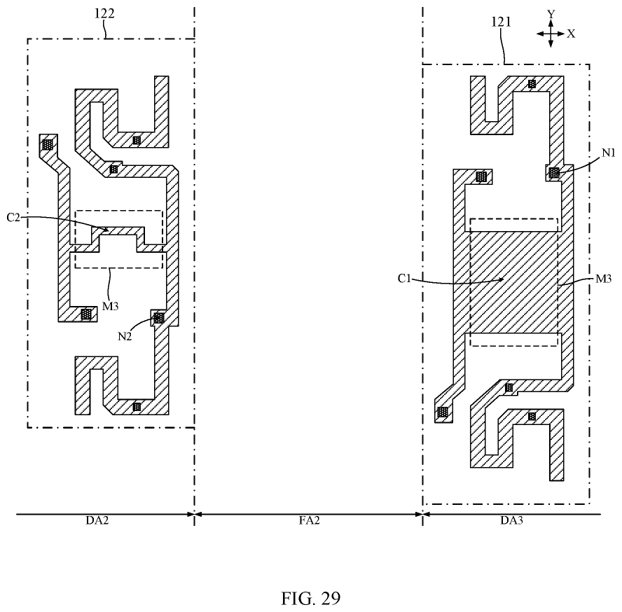

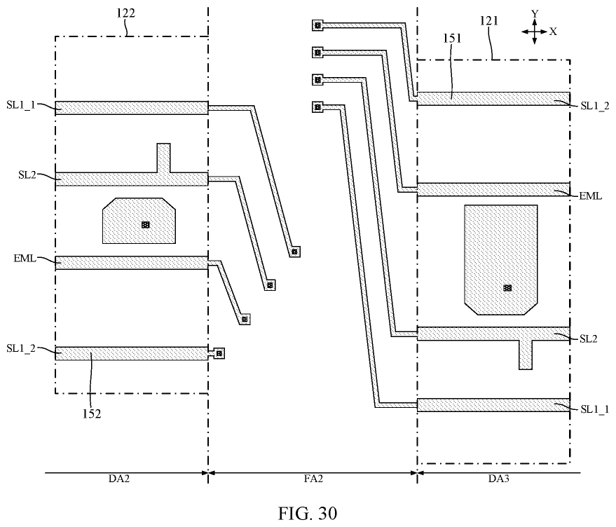

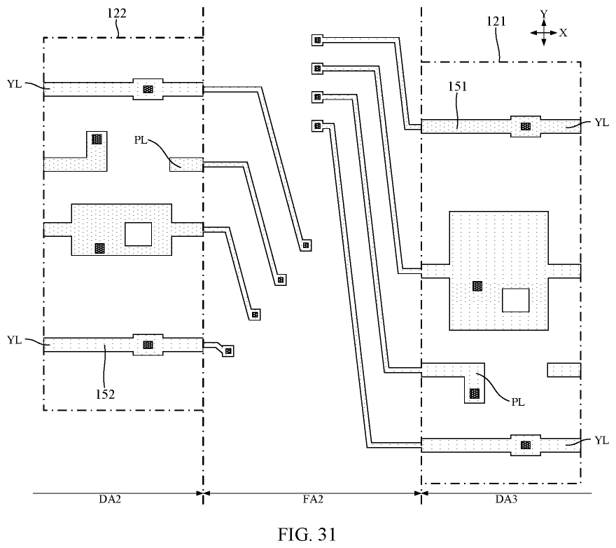

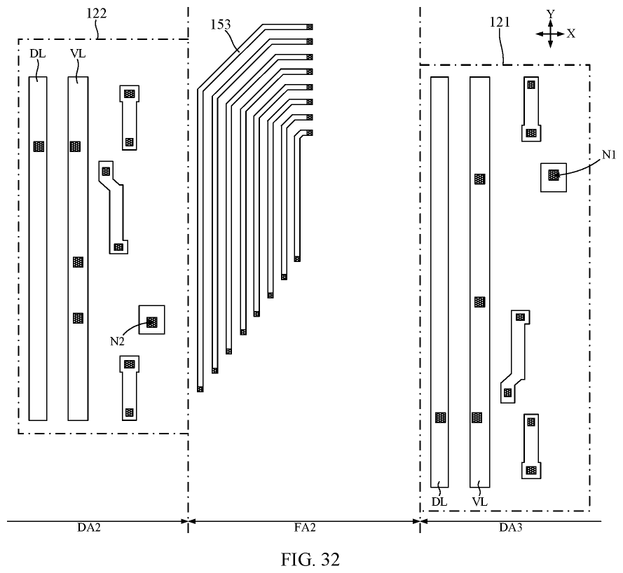

FIG. 29 is a structural schematic diagram showing a semiconductor layer of a first pixel circuit and a second pixel circuit in a display panel according to another embodiment of the present disclosure; FIG. 30 is a structural schematic diagram showing a first metal layer of a first pixel circuit and a second pixel circuit in a display panel according to another embodiment of the present disclosure; FIG. 31 is a structural schematic diagram showing a capacitive metal layer of a first pixel circuit and a second pixel circuit in a display panel according to another embodiment of the present disclosure; and FIG. 32 is a structural schematic diagram showing a second metal layer of a first pixel circuit and a second pixel circuit in a display panel according to another embodiment of the present disclosure.

In an embodiment, a width-to-length of the driving transistor M3 of the first pixel circuit 121 is different from a width-to-length of the driving transistor M3 of the second pixel circuit 122. In an embodiment, a width-to-length of the driving transistor M3 of the first pixel circuit 121 is larger than a width-to-length pf the driving transistor M3 of the second pixel circuit 122.

The larger the width-to-length of the driving transistor M3 of the first pixel circuit 121 is, the stronger the driving capability is. When each first pixel circuit 121 needs to be connected to multiple first light-emitting elements 111 of a same color, the working efficiency and performance of the first pixel circuit 121 can be ensured, thereby achieving the display effect. In some other embodiments, when the number of the second light-emitting elements 112 correspondingly connected to the second pixel circuit 122 is larger, the width-to-length of the driving transistor M3 of the second pixel circuit 122 can also be increased, which will not be elaborated herein. The second pixel circuit 123 can also adjust the above parameters correspondingly according to the number of the third light-emitting elements 113 connected thereto, which will not be elaborated herein.

As shown in FIG. 27 and FIG. 28, in some embodiments, the display panel 100 further includes multiple second signal lines 150. At least one second signal line 150 includes a fourth signal sub-line 151, a fifth signal sub-line 152 and a sixth signal sub-line 153. The fourth signal sub-line 151 extends along the first direction X in the third display region DA3, and is electrically connected to the first pixel circuits 121. The fifth signal sub-line 152 extends along the first direction X, in the second display region DA2 and is electrically connected to the second pixel circuits 122. The sixth signal sub-line 153 extends in the second fan-out region FA2 and is electrically connected to the first signal sub-line 141 and the second signal sub-line 142. Each first pixel circuit 121 is electrically connected to N second signal lines 150, where N is an integer greater than or equal to 2. Among the N second signal lines 150 corresponding to each first pixel circuit 121, the arrangement order of N fourth signal sub-lines 151 along the second direction Y is opposite to the arrangement order of N fifth signal sub-lines 152 along the second direction Y.

By setting the second fan-out region FA2, N fourth signal sub-lines 151 and N fifth signal sub-lines 152 can achieve wire changing by the through-hole by the corresponding N sixth signal sub-lines 153 in the second fan-out region FA2, to achieve changing of the arrangement order in the second direction Y. In an example, a row of the first pixel circuits 121 and the third pixel circuits 123 and a corresponding row of the second pixel circuits 122 share multiple second signal lines 150. The multiple second signal lines 150 have different arrangement orders in different display regions. In the second display region DA2, from top to bottom along the second direction Y, the multiple fourth signal sub-lines 151 are the reference voltage signal line YL, the first scan line SL1_1, the shielding line PL, the second scan line SL2, the light-emitting control line EML, the reference voltage signal line YL, and the first scan line SL1_2 in sequence. In the third display region DA3, also from top to bottom along the second direction Y, the multiple fifth signal sub-lines 152 are the first scan line SL1_2, the reference voltage signal line YL, the emission control line EML, the second scan line SL1_2, the shielding line PL, the first scan line SL1_1, and the reference voltage signal line YL in sequence; and the arrangement order of the multiple fifth signal sub-lines 152 is opposite to the arrangement order of the multiple fourth signal sub-lines 151.

In an embodiment, multiple fourth signal sub-lines 151 and multiple fifth signal sub-lines 152 are arranged in the first metal layer and the capacitor metal layer. Among multiple sixth signal sub-lines 153, at least a part of each sixth signal sub-line 153 is located in the second metal layer, so that the fourth signal sub-line 151 and the corresponding fifth signal sub-line 152 are electrically connected by wire changing. In some other embodiments, for example, the display panel further includes a third metal layer, at least a part of each sixth signal sub-line 153 may be located in the third metal layer, or the sixth signal sub-line 153 may be separately located in the second metal layer and the third metal layer. By configuring at least a part of the sixth signal sub-line 153 to be in a layer different from the fourth signal sub-line 151 and the fifth signal sub-line 152, it can avoid signal interference between the sixth signal sub-lines 153 transmitting different signals, thereby achieving change of the arrangement order of N second signal lines 150 along the second direction Y.

Another aspect of the present disclosure further provides a display device, which is, for example, an electronic device with a display function, such as a mobile phone and a tablet computer. The display device includes the display panel 100 described in any of the foregoing embodiments. The display panel 100 has a first display region DA1, a second display region DA2, a third display region DA3, and a first fan-out region FA1. The third display region DA3 is located at least one side of the first display region DA1 in the first direction X. The second display region DA2 at least partially surrounds the first display region DA1 and the third display region DA3. A light transmittance of the first display region DA1 is greater than a light transmittance of the second display region DA2. The first fan-out region FA1 is located between the third display region DA3 and the second display region DA2, and between the first display region DA1 and the second display region DA2 in a second direction Y. The second direction Y intersects with the first direction X

The display panel 100 further includes first light-emitting elements 111 and first pixel circuits 121. The first light-emitting elements 111 are arranged in the first display region DA1. The first pixel circuits 121 are located in the third display region DA3. The first pixel circuit 121 includes a first connection point P1. The first connection point P1 is electrically connected to at least one first light-emitting element 111 through a first connection line CL1. Each first pixel circuit 121 includes a first preset transistor. The first preset transistor includes a first channel C1. In an embodiment, in at least one first pixel circuit 121 adjacent to the first fan-out region FA1, the first connection point P1 is located at a side of the first channel C1 facing away from the first fan-out region FA1.

In the display panel 100 of the display device according to the present disclosure, in at least one first pixel circuit 121 adjacent to the first fan-out region FA1, the first connection point P1 is located at a side of the first channel C1 facing away from the first fan-out region FA1, such that the first connection line CL1 corresponding to the connection point extends at a side of the first pixel circuit 121 facing away from the first fan-out region FA1, thereby reducing a space of the first fan-out region FA1 occupied by the first connection line CL1, and thus facilitating the arrangement of other signal lines in the first fan-out region FA1 and alleviating a problem of insufficient wiring space in the first fan-out region FA1.

In accordance with the embodiments of the present disclosure as described above, these embodiments do not exhaustively describe all the details and do not limit the present disclosure to only the specific embodiments described. Obviously, many modifications and variations are possible in light of the above description. These embodiments are selected and described in this specification to better explain the principle and practical application of the present disclosure, so that those skilled in the art can make good use of the present disclosure and make modifications based on the present disclosure. The present disclosure is to be limited only by the claims and their full scope and equivalents.

What is claimed is:

1. A display panel comprising:
a first display region;
a second display region; a third display region;
a first fan-out region; first light-emitting elements; and
first pixel circuits,
wherein the third display region is located at least one side of the first display region in a first direction, the second display region at least partially surrounds the first display region and the third display region, a light transmittance of the first display region is greater than a light transmittance of the second display region, the first fan-out region is located between the third display region and the second display region and between the first display region and the second display region in a second direction, and the second direction intersects with the first direction;
wherein the first light-emitting elements are arranged in the first display region;
wherein the first pixel circuits are arranged in the third display region, each of the first pixel circuits comprises a first connection point electrically connected to at least one of the first light-emitting elements through a first connection line, and each of the first pixel circuits comprises a first preset transistor having a first channel, and
wherein, in at least one of the first pixel circuits adjacent to the first fan-out region, the first connection point of each of the at least one of the first pixel circuits is located at a side of the first channel facing away from the first fan-out region.

2. The display panel according to claim 1, wherein the first pixel circuits are arranged in rows along the second direction; and, in each row of the first pixel circuits, the first pixel circuits are arranged along the first direction; and
wherein, in at least one row of the first pixel circuits adjacent to the first fan-out region, the first connection point of each first pixel circuit comprised in the at least one row of the first pixel circuits is located at a side of the first channel facing away from the first fan-out region.

3. The display panel according to claim 1, wherein the first connection point of each of the first pixel circuits is located at a side of the first channel facing away from the first fan-out region.

4. The display panel according to claim 1, wherein one of the first pixel circuits comprises a first node configured to transmit a driving current to one of the first light-emitting elements, and the first node is located at a side of the channel.

5. The display panel according to claim 4, wherein, in at least one of the first pixel circuits, the first connection point of each of the at least one of the first pixel circuits coincides with the first node.

6. The display panel according to claim 4, wherein, in at least one of the first pixel circuits, the first node of each of the at least one of the first pixel circuits is located at a side of the first channel facing the first fan-out region, and the first connection point is electrically connected to the first node through a second connection line.

7. The display panel according to claim 4, further comprising:
second light-emitting elements arranged in the second display region;
third light-emitting elements arranged in the third display region;
second pixel circuits arranged in the second display region, wherein each of the second pixel circuits is electrically connected to at least one of the second light-emitting elements;
third pixel circuits located in the third display region, wherein each of the third pixel circuits is electrically connected to at least one of the third light-emitting elements; and
first signal lines, wherein at least one of the first signal lines comprises a first signal sub-line, a second signal sub-line, and a third signal sub-line; the first signal sub-line extends along the second direction in the third display region and is electrically connected to multiple first pixel circuits of the first pixel circuits, the second signal sub-line extends along the second direction in the second display region and is connected to multiple second pixel circuits of the second pixel circuits, and the third signal sub-line extends in the first fan-out region and is electrically connected to the first signal sub-line and the second signal sub-line.

8. The display panel according to claim 7, wherein the first signal lines comprise at least one of a data line, a reference voltage signal line, or a power supply line.

9. The display panel according to claim 7, wherein each of the second pixel circuits comprises a second preset transistor, the second preset transistor has a second channel, each of the second pixel circuits comprises a second node configured to transmit a driving current to the at least one of the second light-emitting elements, and the second node is located at a side of the second channel.

10. The display panel according to claim 9, wherein an orientation of the first node in each of the first pixel circuit relative to the first channel is opposite to an orientation of the second node in each of the second pixel circuit relative to the second channel.

11. The display panel according to claim 9, wherein an orientation of the first node in each of the first pixel circuits relative to the first channel is the same as an orientation of the second node in each of the second pixel circuits relative to the second channel.

12. The display panel according to claim 7, wherein at least one of the third pixel circuits comprises a third connection point through which the at least one of the third light-emitting elements is electrically connected to the third pixel circuit, each of the third pixel circuits comprises a third preset transistor having a third channel; and
wherein, in at least one of the third pixel circuits adjacent to the first fan-out region, the third connection point is located at a side of the third channel facing away from the first fan-out region.

13. The display panel according to claim 12, wherein the first pixel circuits and the third pixel circuits are arranged in rows along the second direction, in each row of the first pixel circuits and the third pixel circuits, multiple first pixel circuits of the first pixel circuits and multiple third pixel circuits of the third pixel circuits are arranged along the first direction; and
wherein, in at least one row of the first pixel circuits and the third pixel circuits adjacent to the first fan-out region, the first connection point of each of the first pixel circuits is located at a side of the first channel facing away from the first fan-out region, and the third connection point of each of the third pixel circuits is located at a side of the third channel facing away from the first fan-out region.

14. The display panel according to claim 12, wherein one of the third pixel circuits comprises a third node configured to transmit a driving current to the at least one of the third light-emitting elements, the third node is located at a side of the channel, and the third connection point is electrically connected to the third node through a third connection line.

15. The display panel according to claim 1, further comprising:
a second fan-out region located between the third display region and the second display region along the first direction
second light-emitting elements;
second pixel circuits arranged in the second region, wherein each of is the second pixel circuits are electrically connected to at least one of the second light-emitting elements;
second signal lines, at least one of which comprises a fourth signal sub-line, a fifth signal sub-line, and a sixth signal sub-line, wherein the fourth signal sub-line extends along the first direction in the third display region and is electrically connected to the first pixel circuits, the fifth signal sub-line extends along the first direction in the second display region and is electrically connected to the second pixel circuits, and the sixth signal sub-line extends in the second fan-out region and is electrically connected to the fourth signal sub-line and the fifth signal sub-line.

16. The display panel according to claim 15, wherein each of the first pixel circuits is electrically connected to N second signal lines of the second signal lines, and N is an integer greater than or equal to 2; and
wherein, among the N second signal lines corresponding to each of the first pixel circuits, an arrangement order of N fourth signal sub-lines along the second direction is opposite to an arrangement order of N fifth signal sub-lines along the second direction.

17. The display panel according to claim 15, wherein the second signal lines comprise at least one of a scan line, a reference voltage signal line, or a light-emitting control line.

18. A display device, comprising a display panel comprising:
a first display region;
a second display region;
a third display region;
a first fan-out region
first light-emitting elements; and
first pixel circuits,
wherein the third display region is located at least one side of the first display region in a first direction, the second display region at least partially surrounds the first display region and the third display region, a light transmittance of the first display region is greater than a light transmittance of the second display region, the first fan-out region is located between the third display region and the second display region and between the first display region and the second display region in a second direction, and the second direction intersects with the first direction;
wherein the first light-emitting elements are arranged in the first display region;
wherein the first pixel circuits are arranged in the third display region, each of the first pixel circuits comprises a first connection point electrically connected to at least one of the first light-emitting elements through a first connection line, and each of the first pixel circuits comprises a first preset transistor having a first channel, and
wherein, in at least one of the first pixel circuits adjacent to the first fan-out region, the first connection point of each of the at least one of the first pixel circuits is located at a side of the first channel facing away from the first fan-out region.
